(19) United States
(12) Patent Application Publication
(10) Pub. No.: US 2017/0079141 A1
(43) Pub. Date: Mar. 16, 2017

(54) ANISOTROPIC CONDUCTIVE FILM AND PRODUCTION METHOD OF THE SAME

(71) Applicant: DEXERIALS CORPORATION, Tokyo (JP)

(72) Inventors: Masaaki HATTORI, Kanuma-shi (JP); Reiji TSUKAO, Utsunomiya-shi (JP)

(73) Assignee: DEXERIALS CORPORATION, Tokyo (JP)

(21) Appl. No.: 15/122,458

(22) PCT Filed: Feb. 6, 2015
(86) PCT No.: PCT/JP2015/053340

§ 371 Date: Aug. 30, 2016

(30) Foreign Application Priority Data
Mar. 7, 2014 (JP) 2014-045545

(51) Int. Cl. H05K 1/18; B32B 5/16; B32B 37/12; B32B 37/10; H05K 3/30; B32B 7/12

(52) U.S. Cl. CPC H05K 1/181; H05K 3/305; B32B 7/12; B32B 37/12; B32B 37/10; B32B 5/16; B32B 2307/202; B32B 2457/00

(57) ABSTRACT

An anisotropic conductive film of the present invention has a structure in which conductive particles are dispersed or arranged in a regular pattern in an insulating binder layer. A low-adhesive region having a lower adhesive strength than that of the insulating binder layer is formed at a part of a surface of the anisotropic conductive film. The low-adhesive region is a region where a recess portion formed in the insulating binder layer is filled with a low-adhesive resin.

### TECHNICAL FIELD

The present invention relates to an anisotropic conductive film and a production method of the same.

### BACKGROUND ART

An anisotropic conductive film has been widely used in flip-chip mounting of an IC chip on a substrate. In such flip-chip mounting, bumps having a height of 10 to 20 μm are formed on an end part region of a junction surface of the IC chip. Therefore, the IC chip is pushed onto the substrate during anisotropic conductive connection, and the anisotropic conductive film, while the state thereof is maintained, is cured. In this case, a central region of the IC chip where bumps are not formed is cured with warped toward the substrate. For this reason, there is a problem in which a warping state that may cause problems such as a decrease in dimension precision and separation of the junction surface cannot be relaxed. In order to solve this problem, a supporting member provided as a reinforcing material, which tolerates the warping, on a back side of the substrate has been proposed (Patent Literature 1).

### CITATION LIST

### Patent Literature

Patent Literature 1: Japanese Patent Application Laid-Open No. 2008-294396

### SUMMARY OF INVENTION

### Technical Problem

However, in Patent Literature 1, an expensive substrate needs to be processed or a totally new substrate needs to be produced. Patent Literature 1 has a problem in which an increase in production cost is not avoided. Further, when a wiring is formed on the back side of the substrate, the wiring needs to be formed so as to avoid the supporting member. Therefore, there is a problem of a decrease in degree of freedom of design of the substrate.

An object of the present invention is to solve the problems in the conventional techniques, and specifically to solve a problem of warping generated in the conventional IC chip and substrate during anisotropic conductive connection without changing the IC chip and the substrate.

### Solution to Problem

In order to solve a problem of warping in an anisotropic conductive film that is a member different from the IC chip and the substrate, the present inventor has variously investigated, and as a result, found that when a portion that is warped in pushing of the IC chip onto the substrate during anisotropic conductive connection, that is, a central region of the IC chip where a bump is not formed is not brought into close contact with and fixed to the anisotropic conductive film, the warping generated during anisotropic conductive connection is relaxed after the anisotropic conductive connection. The present invention thus has been completed.

Specifically, the present invention provides an anisotropic conductive film in which conductive particles are dispersed or arranged in a regular pattern in an insulating binder layer and that has a low-adhesive region that is formed at a part of a surface of the anisotropic conductive film and has a lower adhesive strength than that of the insulating binder layer. A preferable aspect of the low-adhesive region is a region where a recess portion formed in the insulating binder layer is filled with a low-adhesive resin.

The present invention also provides a production method of the anisotropic conductive film characterized by performing a process of forming the low-adhesive region at a part of the surface of the insulating binder layer. Further, the present invention provides a production method of the anisotropic conductive film in which the low-adhesive region is a region where a recess portion formed in the insulating binder layer is filled with a low-adhesive resin, the method including the following steps (A) to (C).

### Step (A)

A step of applying an insulating binder layer-forming composition containing conductive particles to a mold having a projection portion corresponding to the low-adhesive region, and drying the composition by heating or irradiation with ultraviolet light or forming a film to form the insulating binder layer having the recess portion formed on a surface.

### Step (B)

A step of detaching the insulating binder layer from the mold.

### Step (C)

A step of filling the recess portion of the insulating binder layer with a low-adhesive region-forming material.

The present invention also provides a connection structure in which a first electronic component is connected to a second electronic component by anisotropic conductive connection through the aforementioned anisotropic conductive film.

Furthermore, the present invention provides a method of connecting a first electronic component to a second electronic component by anisotropic conductive connection through the aforementioned anisotropic conductive film,

the method including: temporarily adhering the anisotropic conductive film to the second electronic component from a side of the insulating binder layer; mounting the first electronic component on the temporarily adhered anisotropic conductive film; and compression-bonding them from a side of the first electronic component. During the compression-bonding, heating or irradiation with light (ultraviolet light, etc.) may be performed or heating and irradiation with light may be simultaneously performed.

### Advantageous Effects of Invention

In the anisotropic conductive film of the present invention, the conductive particles are dispersed or arranged in a regular pattern in the insulating binder layer, and the low-adhesive region having a lower adhesive strength than that of the insulating binder layer is formed at a part of a surface of the anisotropic conductive film. For this reason, a central region of an IC chip where a bump is not formed cannot be brought into close contact with and fixed to the anisotropic conductive film, and a warping generated during anisotropic conductive connection can be relaxed.

### BRIEF DESCRIPTION OF DRAWINGS

FIG. 1A is a cross-sectional view of an anisotropic conductive film of the present invention.

FIG. 1B is a cross-sectional view of an anisotropic conductive film of the present invention.

FIG. 2 is a cross-sectional view of an anisotropic conductive film of the present invention.

FIG. 3 is a view illustrating a case where an IC chip is connected to a glass substrate by anisotropic conductive connection through the anisotropic conductive film.

FIG. 4 is a plan view of an anisotropic conductive film of the present invention.

FIG. 5 is a plan view of an anisotropic conductive film of the present invention.

### DESCRIPTION OF EMBODIMENTS

Hereinafter, the anisotropic conductive film of the present invention will be described in detail.

### <<Anisotropic Conductive Film>>

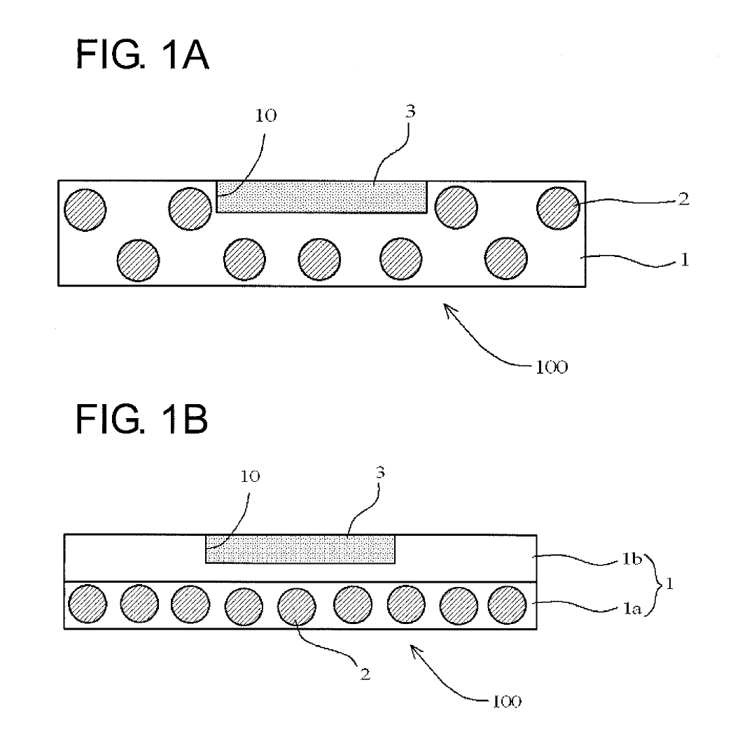

As shown in FIG. 1A, an anisotropic conductive film 100 is an anisotropic conductive film in which conductive particles 2 are dispersed or arranged in a regular pattern in an insulating binder layer 1 and that has a structure in which a low-adhesive region 3 having a lower adhesive strength than that of the insulating binder layer 1 is formed at a part of at least a surface of the anisotropic conductive film.

When the conductive particles 2 are arranged in a regular pattern, the insulating binder layer 1 may be composed of a conductive particle-holding layer 1a that holds the conductive particles 2 and an insulating adhesion layer 1b that is layered on the conductive particle-holding layer 1a, as shown in FIG. 1B. In the insulating adhesion layer 1b, the low-adhesive region 3 is formed.

Examples of a procedure of achieving the low adhesive properties of the low-adhesive region 3 may include a procedure using a low-adhesive material and a procedure of forming a fine grating structure or a fine irregular structure on the insulating binder layer 1 using a publicly known procedure.

It is preferable that the total thickness of the whole anisotropic conductive film be 10 μm or more and 60 μm or less.

### <Low-Adhesive Region>

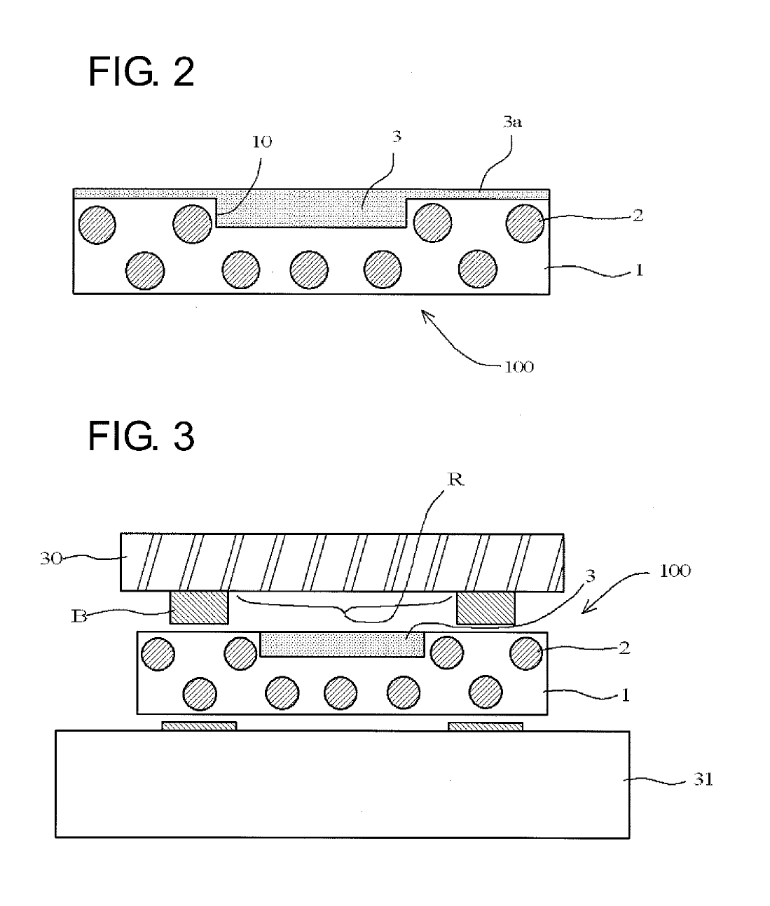

A preferable aspect of the low-adhesive region 3 is an aspect in which a low-adhesive material is used. Specifically, the preferable aspect is an aspect in which a recess portion 10 that is formed in the insulating binder layer 1 or the insulating adhesion layer 1b and has preferably a depth of 2 μm or more and 30 μm or less, and more preferably 5 μm or more and 15 μm or less is filled with a low-adhesive resin as shown in FIGS. 1A and 1B. Further, it is preferable that the recess portion 10 be 10% or more and 50% or less, and more preferably 20% or more and 50% or less of the thickness of the film. In this case, as shown in FIG. 2, at a region other than the low-adhesive region 3 on the surface of the insulating binder layer 1 in which the recess portion 10 is formed, a layer that is thinner than the recess portion 10 may also be formed of the same material as that for the insulating binder layer 1 in such a range that the adhesive strength of the insulating binder layer 1 is not impaired (in other words, in such a range that the low-adhesive region is excluded from a connection region during anisotropic conductive connection). Specifically, a thin film 3a having a thickness of preferably 0.2 μm or more and 6 μm or less, and more preferably 0.3 μm or more and 4 μm or less may be formed of the low-adhesive resin. In this case, an effect of relaxing a production condition can be obtained as compared with a case where only the recess portion 10 is filled with the low-adhesive resin. The low-adhesive resin is preferred in economic terms since the electrical connection is not related and the resin does not contain conductive particles. It is preferable that the thin film 3a be 3% or more and 20% or less of the depth of the recess portion 10. When the thin film 3a is thicker than this range, a difference of adhesion force of solving bending in an in-plane direction is unlikely to be generated. When the thin film 3a is thinner, the uniformity of coating thickness cannot be secured, and the quality of an elongated film is affected.

It is preferable that the low-adhesive region 3 exist in a range that is preferably 20% or more and 80% or less, and more preferably 30% or more and 70% or less of the whole width of the anisotropic conductive film. It is desirable that this range exist at a central region in a width direction.

The shape of the recess portion 10 in a case illustrated in FIGS. 1A and 1B is configured such that an angle formed between a surface of the anisotropic conductive film and an inner side surface of the recess portion is a right angle and an angle formed between the inner side surface and a bottom surface of the recess portion is also a right angle. The recess portion 10 may have a concave shape in which the width is increased from the bottom surface to an opening portion. The inner side surface of the recess portion may be formed linearly in a thickness direction, or formed in a curved shape. For example, the recess portion may have a hemispherical shape. Thus, a shape formed of the low-adhesive resin can be easily produced with good precision. The adhesion force can also be locally adjusted. This is because an abrupt change of the adhesion force in a surface direction is not caused.

Herein, the low-adhesive region 3 having a lower adhesive strength than that of the insulating binder layer 1 is provided at a part of a surface of the insulating binder layer 1. A degree of low adhesive strength represents such a low degree that a warping generated in an IC chip during anisotropic conductive connection can be relaxed after the anisotropic conductive connection. It is preferable that the adhesion strength of the low-adhesive region 3 be 5% or more and 50% or less, and more preferably 20% or more and 40% or less of that of the insulating binder layer 1 at the region other than the low-adhesive region. Each adhesion strength can be measured at room temperature using a die shear measurement device (trade name: Dage 2400, manufactured by DACE). In general, the adhesion strength of the low-adhesive region 3 is preferably 300 N or less, and the adhesion strength of the insulating binder layer 1 at the other region is preferably 600 N or more.

When a composition of the low-adhesive region 3 and a composition of the other region are the same, an absolute value of detection peak by FT-IR of a specific functional group in the low-adhesive region 3 in an uncured state is preferably less than 80%, more preferably 70% or less, and further preferably 50% or less of the detection peak in the other region. A relative ratio of these detection peaks can be determined in the same manner as in a publicly known procedure used to determine a reaction ratio from a decrease ratio of a functional group in the polymerization of an epoxy compound or an acrylic monomer.

As the low-adhesive resin to be filled with in the recess portion 10 as shown in FIG. 2, a resin that does not contain a curing component and exhibit tackiness can be used. Examples of the low-adhesive resin may include a film-forming resin having a glass transition point of −30° C. or higher and 70° C. or lower. Specific examples thereof may include publicly known resins used for ACF, such as a phenoxy resin and an acrylic rubber. The low-adhesive resin may contain a polymerizable resin such as an epoxy compound and an acrylic compound, and the content of the low-adhesive resin in the recess portion is preferably 50% or less, more preferably 5% or more and 50% or less, and further preferably 10% or more and 40% or less of the content thereof in the region other than the recess portion. When the curing component is not contained or the amount thereof is too small, a portion where the adhesion strength is changed abruptly is formed in a cured film. Therefore, other problems such as floating may arise. In order to suppress such a change, it is preferable that the shape of the recess portion be inclined so that the width on a side of the film surface is wider than that of the bottom of the recess portion.

The low-adhesive region 3 can be configured by the same material as that for the other region. However, when the mixing amount of curing component such as an epoxy compound and an acrylic compound is 80% or less of that in the other region or a reaction initiator is not contained, a function of the low-adhesive region can be exerted. The low-adhesive region and the other region can be distinguished by a change ratio in a decrease ratio of functional group in FT-IR measurement, and the low-adhesive region is a region where the change ratio is relatively small.

The low-adhesive region 3 is provided to decrease a residual stress generated in the anisotropic conductive film during anisotropic conductive connection. Therefore, it is preferable that the position where the low-adhesive region 3 is provided be at a region that is outside of a region that directly contributes to anisotropic connection and has the largest stress change. For example, the position is a region that corresponds to a region that is warped during anisotropic conductive connection of an IC chip 30 having a bump B at an end part to a wiring of a glass substrate 31 through the anisotropic conductive film 100 (for example, a central portion R surrounded by the bump B of the IC chip 30 having the bump B formed at the end part thereof), as shown in FIG. 3.

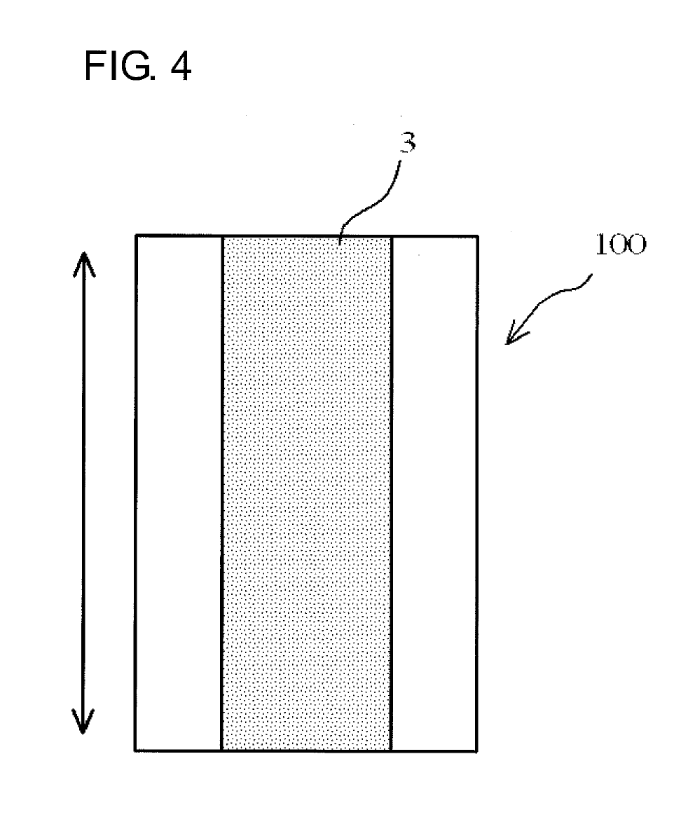

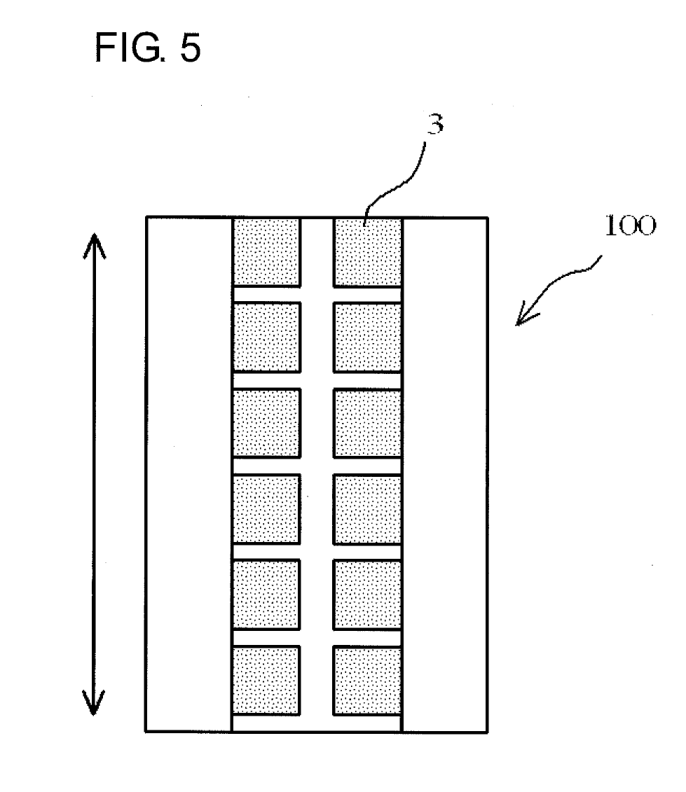

As shown in FIG. 4, the low-adhesive region 3 may be elongated in a longitudinal direction (arrow direction) of the anisotropic conductive film 100 (the width thereof is preferably 15 μm or more, more preferably 50 μm or more, and particularly preferably 150 μm to 5 mm). As shown in FIG. 5, the low-adhesive regions 3 may be discontinuously provided in the longitudinal direction (arrow direction) of the anisotropic conductive film 100 in an intermittent pattern.

### <Insulating Binder Layer and Conductive Particle-Holding Layer>

The insulating binder layer 1 (FIG. 1A) or the conductive particle-holding layer 1a (FIG. 1B) constituting the anisotropic conductive film 100 of the present invention is a film formed of a mixture of a film-forming resin such as a phenoxy resin, an epoxy resin, an unsaturated polyester resin, a saturated polyester resin, a urethane resin, a butadiene resin, a polyimide resin, a polyamide resin, or a polyolefin resin with a thermally or photo-polymerizable resin such as a thermally or photo-cationically, anionically, or radically polymerizable resin, or a polymerized film thereof. It is particularly preferable that the insulating binder layer 1 or the conductive particle-holding layer 1a be a film formed of a mixture containing an acrylate compound and a photo-radical polymerization initiator or a polymerized film thereof. Hereinafter, a case where the insulating binder layer 1 or the conductive particle-holding layer 1a contains a photo-radically polymerizing resin and polymerization is performed will be described.

### (Acrylate Compound)

As an acrylate compound that is an acrylate unit, a conventionally known photo-radically polymerizable acrylate can be used. For example, a monofunctional (meth)acrylate (herein, (meth)acrylate includes acrylate and methacrylate), or a polyfunctional (meth)acrylate such as a bifunctional or more (meth)acrylate can be used. In the present invention, it is preferable that a polyfunctional (meth)acrylate be used for at least a part of an acrylic monomer to form a thermosetting adhesive.

The content of the acrylate compound in the insulating binder layer 1 or the conductive particle-holding layer 1a is preferably 2% by mass or more and 70% by mass or less, and more preferably 10% by mass or more and 50% by mass or less in terms of stability of shape of the recess portion.

### (Photo-Radical Polymerization Initiator)

As the photo-radical polymerization initiator, a publicly known photo-radical polymerization initiator can be appropriately selected and used. Examples of the publicly known photo-radical polymerization initiator may include an acetophenone-based photopolymerization initiator, a benzylketal-based photopolymerization initiator, and a phosphorus-based photopolymerization initiator.

From the viewpoints of sufficient progress of photo-radical polymerization reaction and suppression of decrease in film stiffness, the amount of the photo-radical polymerization initiator to be used is preferably 0.1 parts by mass or more and 25 parts by mass or less, and more preferably 0.5 parts by mass or more and 15 parts by mass or less, relative to 100 parts by mass of the acrylate compound.

From the viewpoints of suppression of decrease in conductive particle capture efficiency and increase in conduction resistance, the thickness of the insulating binder layer 1 is preferably 5 μm or more and 60 μm or less, and more preferably 7 μm or more and 40 μm or less. The thickness of the conductive particle-holding layer 1a is also preferably 1 μm or more and 20 μm or less, and more preferably 2 μm or more and 15 μm or less from the same viewpoints.

The insulating binder layer 1 or the conductive particle-holding layer 1a may further contain an epoxy compound and a thermal or photo-cationic or anionic polymerization initiator. In this case, it is preferable that the insulating adhesion layer 1b be also a thermally or photo-cationically or anionically polymerizable resin layer containing an epoxy compound and a thermal or photo-cationic or anionic polymerization initiator, as described later. Thus, the interlayer adhesion strength can be improved. The epoxy compound and the thermal or photo-cationic or anionic polymerization initiator will be described later.

The insulating binder layer 1 can be formed by, for example, applying a photo-radically polymerizable composition containing a photo-radically polymerizable acrylate, a photo-radical polymerization initiator, and conductive particles to a mold having a structure required for forming a low-adhesive region 3, and heating the composition or irradiating it with ultraviolet light to dry it (or form a film). The conductive particle-holding layer 1a can be formed by attaching the conductive particles using a photo-radically polymerizable composition by a procedure such as a film transfer method, a mold transfer method, an inkjet method, and an electrostatic attachment method, and irradiating them with ultraviolet light from a side of the conductive particles, an opposite side thereof, or both the sides.

### <Insulating Adhesion Layer>

For the insulating adhesion layer 1b that is layered on the conductive particle-holding layer 1a, the same material as that for the conductive particle-holding layer 1a can be used.

From the viewpoints of the recess portion being held and sufficient adhesion strength, the thickness of the insulating adhesion layer 1b is preferably larger than 2 μm and less than 30 μm, and more preferably larger than 5 μm and less than 15 μm.

### (Epoxy Compound)

When the insulating adhesive layer 1b is a thermally or photo-cationically or anionically polymerizable resin layer containing an epoxy compound and a thermal or photo-cationic or anionic polymerization initiator, examples of the epoxy compound may include a compound or a resin having two or more epoxy groups in the molecule. The compound and the resin may be liquid or solid.

### (Thermal Cationic Polymerization Initiator)

As the thermal cationic polymerization initiator, a publicly known thermal cationic polymerization initiator for an epoxy compound can be used. For example, the thermal cationic polymerization initiator generates an acid, which can cationically polymerize a cationically polymerizable compound, by heat. A publicly known iodonium salt, sulfonium salt, phosphonium salt, or ferrocenes can be used. An aromatic sulfonium salt that exhibits favorable latency for temperature can be preferably used.

From the viewpoints of suppression of curing failure and reduced product life, the amount of the thermal cationic polymerization initiator to be added is preferably 2 to 60 parts by mass, and more preferably 5 to 40 parts by mass, relative to 100 parts by mass of the epoxy compound.

### (Thermal Anionic Polymerization Initiator)

As the thermal anionic polymerization initiator, a publicly known thermal anionic polymerization initiator for an epoxy compound can be used. For example, the thermal anionic polymerization initiator generates a base, which can anionically polymerize an anionically polymerizable compound, by heat. A publicly known aliphatic amine-based compound, aromatic amine-based compound, secondary or tertiary amine-based compound, imidazole-based compound, polymercaptan-based compound, boron trifluoride-amine complex, dicyandiamide, or organic acid hydrazide can be used. An encapsulated imidazole-based compound that exhibits favorable latency for temperature can be preferably used.

When the amount of the thermal anionic polymerization initiator to be added is too small, curing tends to be difficult. When the amount is too large, the product life tends to be reduced. Therefore, the amount is preferably 2 parts by mass or more and 60 parts by mass or less, and more preferably 5 parts by mass or more and 40 parts by mass or less, relative to 100 parts by mass of the epoxy compound.

### (Photo-Cationic Polymerization Initiator and Photo-Anionic Polymerization Initiator)

As the photo-cationic polymerization initiator or the photo-anionic polymerization initiator for an epoxy compound, a publicly known polymerization initiator can be appropriately used.

### (Acrylate Compound)

When the insulating adhesive layer 1b is a thermally or photo-radically polymerizable resin layer containing an acrylate compound and a thermal or photo-radical polymerization initiator, the acrylate compound described in relation to the insulating binder layer 1 can be appropriately selected and used.

### (Thermal Radical Polymerization Initiator)

Examples of the thermal radical polymerization initiator may include an organic peroxide and an azo-based compound. An organic peroxide that does not generate nitrogen causing bubbles can be preferably used.

When the amount of the thermal radical polymerization initiator to be used is too small, curing is difficult. When the amount is too large, the product life is reduced. Therefore, the amount is preferably 2 parts by mass or more and 60 parts by mass or less, and more preferably 5 parts by mass or more and 40 parts by mass or less, relative to 100 parts by mass of the acrylate compound.

### (Photo-Radical Polymerization Initiator)

As the photo-radical polymerization initiator for an acrylate compound, a publicly known photo-radical polymerization initiator can be used.

When the amount of the photo-radical polymerization initiator to be used is too small, curing is difficult. When the amount is too large, the product life is reduced. Therefore, the amount is preferably 1 parts by mass or more and 60 parts by mass or less, and more preferably 3 parts by mass or more and 40 parts by mass or less, relative to 100 parts by mass of the acrylate compound.

On another surface of the insulating binder layer 1, another insulating adhesion layer may be layered. Thus, an effect capable of finely controlling the fluidity of the whole layer can be obtained. Herein, the other insulating adhesion layer may have the same configuration as that of the insulating adhesion layer 1b.

### <Conductive Particles>

As the conductive particles 2, conductive particles used in conventionally known anisotropic conductive films can be appropriately selected and used. Examples of the conductive particles may include metal particles such as nickel, cobalt, silver, copper, gold, and palladium particles, and metal-coated resin particles. Two or more kinds thereof may be used in combination.

In order to correspond to dispersion of wiring height, suppress an increase in conduction resistance, and suppress occurrence of short circuit, the average particle diameter of the conductive particles 2 is preferably 1 μm or more and 10 μm or less, and more preferably 2 μm or more and 6 μm or less. The average particle diameter can be measured by a general particle size distribution measurement device.

In order to suppress a decrease in conductive particle capture efficiency and suppress occurrence of short circuit, the amount of the conductive particles 2 existing in the insulating binder layer 1 is preferably 50 particles or more and 40,000 particles or less, and more preferably 200 particles or more and 20,000 particles or less per square millimeter.

### “Arrangement of Conductive Particles 2 in Regular Pattern”

A regular pattern in the arrangement of the conductive particles 2 in the regular pattern means an arrangement in which the conductive particles 2 that can be recognized when the conductive particles 2 are viewed from a surface of the anisotropic conductive film 100 exist at a point of a lattice such as a rectangular lattice, a square lattice, a hexagonal lattice, and a rhombic lattice. Virtual lines constituting the lattices may be straight lines, curves, or bent lines.

The ratio of the conductive particles 2 arranged in the regular pattern to the whole conductive particles 2 is preferably 90% or more in terms of the number of the conductive particles for stabilization of anisotropic connection. This ratio can be measured using an optical microscope or the like.

When the interparticle distance of the conductive particles 2, that is, the closest distance between the conductive particles is preferably 0.5 times or more, and more preferably 1 time or more and 5 times or less the average particle diameter of the conductive particles 2.

### <<Production Method of Anisotropic Conductive Film>>

Next, an example of a production method of the anisotropic conductive film of the present invention will be described.

The anisotropic conductive film of the present invention can be produced by performing a process of forming a low-adhesive region at a part of a surface of the insulating binder layer. Examples of the process of forming a low-adhesive region may include a process including potting a low-adhesive region-forming material and smoothing the material by a publicly known procedure, performing grating processing by a laser, or performing micro-uneven processing by a photolithography method.

A preferable example of the production method of the anisotropic conductive film of the present invention is a production method including the following steps (A) to (C). Hereinafter, each step will be described.

### Step (A)

An insulating binder layer-forming composition containing conductive particles is first applied to a mold having a projection portion corresponding to the low-adhesive region, and the composition is dried by heating or irradiation with ultraviolet light or a film is formed, to form the insulating binder layer having the recess portion on a surface. As the mold, a mold formed of a glass, a cured resin, a metal, or the like can be used.

### Step (B)

Subsequently, the insulating binder layer is detached from the mold using a publicly known procedure. At this step, it is preferable that a transfer sheet be temporarily adhered to the insulating binder layer in advance and the insulating binder layer be detached from the mold using the transfer sheet as a support.

### Step (C)

The recess portion of the insulating binder layer is then filled with the low-adhesive region-forming material by a publicly known procedure. Thus, the anisotropic conductive film of a preferable aspect of the present invention is obtained.

If necessary, the transfer sheet is released, and another insulating adhesion layer may be layered on a released surface (another surface of the insulating binder layer).

### <<Application of Anisotropic Conductive Film>>

The anisotropic conductive film obtained in this manner can be preferably applied to anisotropic conductive connection by heat or light between a first electronic component such as an IC chip, an IC module, or a flexible substrate and a second electronic component such as a flexible substrate, a rigid substrate, or a glass substrate (in addition to COG, applicable to COF, COB, FOG, FOB, and the like). A connection structure thus obtained is also a part of the present invention. In this case, it is preferable that the anisotropic conductive film be temporarily adhered to the second electronic component such as a wiring substrate from a side of the insulating binder layer, the first electronic component such as an IC chip be mounted on the anisotropic conductive film temporarily adhered, and the anisotropic conductive film be thermo-compression bonded from a side of the first electronic component since the connection reliability is enhanced. Further, connection can also be achieved by light curing.

### EXAMPLES

Hereinafter, the present invention will be described more specifically by Examples.

### Examples 1 to 5

60 Parts by mass of a phenoxy resin (YP-50, NIPPON STEEL & SUMIKIN CHEMICAL CO., LTD.), 40 parts by mass of an acrylate (EP600, DAICEL-ALLNEX Ltd.), 2 parts by mass of a photo-radical polymerization initiator (IRGACURE 369, Mitsubishi Chemical Corporation), and 10 parts by mass of conductive particles having an average particle diameter of 4 μm (Ni/Au plated resin particles, AUL 704, SEKISUI CHEMICAL CO., LTD.) were mixed in toluene to prepare a mixed liquid having a solid content of 50% by mass.

An insulating binder layer having a width of 2 mm after slitting was formed using this mixed liquid and a sheet-type mold having predetermined projection portion(s) (in Examples 1 to 4, an aspect in which a projection portion was continuously provided in an elongated pattern corresponding to FIG. 4, and in Example 5, an aspect in which projection portions were discontinuously provided in an intermittent pattern corresponding to FIG. 5). This insulating binder layer was detached from the mold, a low-adhesive resin composition was applied to a surface where a recess portion was formed so that the thickness of dried portion other than the recess portion was 3 μm, and then irradiated with ultraviolet light having a wavelength of 365 nm at an integrated light amount of 4,000 mJ/cm². Thus, the insulating binder layer was formed.

To the whole surface of the obtained insulating binder layer on a side of the recess portion, a low-adhesive resin composition obtained by diluting 94 parts by mass of the phenoxy resin, 6 parts by mass of the acrylate, and 0.3 parts by mass of the photo-radical polymerization initiator with toluene was applied so that the thickness of dried portion other than the recess portion was 3 μm, and dried to obtain an anisotropic conductive film having a total thickness of 25 μm.

The area ratio (%) of the recess portion in the surface of the obtained anisotropic conductive film on the side of the recess portion, the depth ratio (%) of the depth (μm) of the recess portion to the total thickness, and the sum of the distance (μm) from one end on the film side to one end of the recess portion and the distance (μm) from another end on the film side to another end of the recess portion were measured using an optical microscope. The depth was calculated from the adjustment of a focal point and determined. The obtained results are shown in Table 1.

### Example 6

### Formation of Insulating Binder Layer in which Conductive Particles are Arranged

60 Parts by mass of a phenoxy resin (YP-50, NIPPON STEEL & SUMIKIN CHEMICAL CO., LTD.), 40 parts by mass of an acrylate (EP600, DAICEL-ALLNEX Ltd.), and 2 parts by mass of a photo-radical polymerization initiator (IRGACURE 369, Mitsubishi Chemical Corporation) were mixed in toluene to prepare a mixed liquid having a solid content of 50% by mass.

This mixed liquid was applied to a polyethylene terephthalate film having a thickness of 50 μm so that a dried thickness was 8 μm, and dried in an oven at 80° C. for 5 minutes, to form a photo-radically polymerizable resin layer.

Conductive particles (Ni/Au-plated resin particles, AUL 704, SEKISUI CHEMICAL CO., LTD.) having an average particle diameter of 4 μm were then arranged at intervals of 4 μm in a single layer on the obtained photo-radically polymerizable resin layer. The photo-radically polymerizable resin layer was further irradiated with ultraviolet light having a wavelength of 365 nm at an integrated light amount of 4,000 mJ/cm² using an LED light source from the side of the conductive particles. Thus, the insulating binder layer in which the conductive particles were fixed on a surface was formed.

### (Formation of Insulating Adhesion Layer Having Recess Portion)

An insulating adhesion layer having a width of 2 mm after slitting and a recess portion at a center was formed using an insulating adhesion layer-forming composition containing 60 parts by mass of the phenoxy resin, 40 parts by mass of the acrylate, and 2 parts by mass of the photo-radical polymerization initiator and a sheet-type mold having a predetermined projection portion (an aspect corresponding to FIG. 4 in which the projection portion was continuously elongated).

### (Production of Anisotropic Conductive Film)

The insulating binder layer was laminated on the obtained insulating adhesion layer under conditions of 40° C. and 0.1 Pa. The obtained layered body was detached from the mold. To the whole surface of the obtained insulating adhesion layer on a side of the recess portion, a low-adhesive resin composition obtained by diluting 80 parts by mass of the phenoxy resin, 20 parts by mass of the acrylate, and 1 part by mass of the photo-radical polymerization initiator with toluene was applied so that the thickness of dried portion other than the recess portion was 3 μm, and dried to obtain an anisotropic conductive film having a total thickness of 28 μm.

The area ratio (%) of the recess portion in the surface of the obtained anisotropic conductive film on the side of the recess portion, the depth ratio (%) of the depth (μm) of the recess portion to the total thickness, and the sum of the distance (μm) from one end of the film to one end of the recess portion and the distance (μm) from another end of the film to another end of the recess portion were measured using an optical microscope. The depth was calculated from the adjustment of a focal point and determined. The obtained results are shown in Table 1.

### Comparative Example 1

An anisotropic conductive film having a total thickness of 25 μm was formed in the same manner as in Example 1 except that a sheet-shaped mold without a recess portion was used and a non-adhesive resin layer was not provided.

The area ratio (%) of the recess portion in the surface of the obtained anisotropic conductive film on the side of the recess portion, the depth ratio (%) of the depth (μm) of the recess portion to the total thickness, and the sum of the distance (μm) from one end on the film side to one end of the recess portion and the distance (μm) from another end on the film side to another end of the recess portion were measured using an optical microscope. The depth was calculated from the adjustment of a focal point and determined. The obtained results are shown in Table 1.

### <Evaluation>

For the anisotropic conductive films of respective Examples and Comparative Examples, (a) short circuit occurrence ratio and (b) amount of warping during anisotropic conductive connection were each evaluated on a test as follows. The results are shown in Table 1.

### (a) Short Circuit Occurrence Ratio

The anisotropic conductive film of each of Examples and Comparative Examples was placed between the IC for evaluation of short circuit occurrence ratio and a glass substrate, and heated and pressurized (at 180° C. and 80 MPa for 5 seconds) to obtain a connection body for various evaluations. The short circuit occurrence ratio of the connection body for evaluation was determined. The short circuit occurrence ratio was calculated by “occurrence number of short circuit/total number of space of 7.5 μm.”

IC for evaluation of short circuit occurrence ratio (comb-teeth TEG (test element group) having a space of 7.5 μm).

Outside diameter: 1.5×13 mm

Thickness: 0.5 mm

Bump specification: gold-plating, height: 15 μm, size: 25×140 μm, gap between bumps: 7.5 μm

### Glass Substrate

Glass material: available from Corning Incorporated

Outside diameter: 30×50 mm

Thickness: 0.5 mm

Electrode: ITO wiring

### (b) Amount of Warping

A warping of the connection body for evaluation formed in (a) at a width of 20 mm on a surface of the glass substrate on a side where the IC chip was not mounted was measured by a three-dimensional measurement device (KEYENCE CORPORATION). In practical terms, the warping is preferably less than 15 μm. This width of 20 mm corresponds to the width of the IC chip mounted on a back side.

TABLE 1

| | | Comparative | | | | | | |
|---|---|---|---|---|---|---|---|---|
| | | Example | Example | | | | | |
| | | 1 | 1 | 2 | 3 | 4 | 5 | 6 |
| Ratio of Area of Recess Portion to | (%) | — | 50 | 50 | 60 | 70 | 50 | 70 |
| Total Area of Surface Having Recess | | | | | | | | |
| Portion | | | | | | | | |
| Ratio of Depth of Recess Portion to | (%) | — | 20 | 50 | 50 | 50 | 50 | 50 |
| Total Thickness of Anisotropic | | | | | | | | |
| Conductive Film | | | | | | | | |
| Sum of Two Distances from End on | (μm) | — | 1000 | 1000 | 800 | 600 | 600 | 600 |
| Film Side to End of Recess Portion | | | | | | | | |
| Short Circuit Occurrence Ratio | (ppm) | <50 | <50 | <50 | <50 | <50 | <50 | <50 |
| Amount of Warping | (μm) | 15 | 10 | 10 | 9 | 8.5 | 10 | 8.5 |

As seen from Table 1, in the anisotropic conductive films of Examples 1 to 6, the short circuit occurrence ratio was not increased, and the amount of warping was made smaller than Comparative Example 1. The ratio of the depth of the recess portion to the total thickness was not largely changed within a range of 20 to 50% (Examples 1 and 2). When the area of the recess portion relative to the surface area of the film was increased, the amount of warping tended to decrease (Examples 2 to 4). The amount of warping in the anisotropic conductive film in which the recess portion was continuously elongated was not largely different from that in the anisotropic conductive film in which the recess portion was dotted (Examples 2 and 5). The amount of warping in the anisotropic conductive film in which the conductive particles were randomly dispersed was not largely different from that in the anisotropic conductive film in which the conductive particles were arranged.

### INDUSTRIAL APPLICABILITY

In the anisotropic conductive film of the present invention, the conductive particles are dispersed or arranged in a regular pattern in the insulating binder layer, and the low-adhesive region having a lower adhesive strength than that of the insulating binder layer is formed at a part of a surface of the insulating binder layer. For this reason, a central region of an IC chip where a bump is not formed cannot be brought into close contact with and fixed to the anisotropic conductive film, and a warping generated during anisotropic conductive connection can be relaxed. Therefore, the anisotropic conductive film is useful in anisotropic conductive connection of an electronic component such as an IC chip to a wiring substrate.

### REFERENCE SIGNS LIST

1 insulating binder layer
1a conductive particle-holding layer
1b insulating adhesion layer
2 conductive particle
3 low-adhesive region
10 recess portion
30 IC chip
31 glass substrate
B bump
100 anisotropic conductive film

1. An anisotropic conductive film in which conductive particles are dispersed or arranged in a regular pattern in an insulating binder layer, wherein a low-adhesive region that has a lower adhesive strength than that of the insulating binder layer is formed at a part of a surface of the anisotropic conductive film.

2. The anisotropic conductive film according to claim 1, wherein the low-adhesive region is a region where a recess portion formed in the insulating binder layer is filled with a low-adhesive resin.

3. The anisotropic conductive film according to claim 2, wherein a layer that is thinner than the recess portion is also formed of the same material as that for the insulating binder layer at a region other than the low-adhesive region on the surface of the insulating binder layer in which the recess portion is formed.

4. The anisotropic conductive film according to claim 1, wherein the low-adhesive resin does not contain conductive particles.

5. The anisotropic conductive film according to claim 1, wherein the low-adhesive region is elongated in a longitudinal direction of the anisotropic conductive film.

6. The anisotropic conductive film according to claim 1, wherein the low-adhesive regions are intermittently provided in a longitudinal direction of the anisotropic conductive film.

7. A production method of the anisotropic conductive film according to claim 1, the method comprising performing a process of forming the low-adhesive region at a part of the surface of the insulating binder layer.

8. A production method of the anisotropic conductive film according to claim 2, the method comprising the following steps (A) to (C):
Step (A)
a step of applying an insulating binder layer-forming composition containing conductive particles to a mold having a projection portion corresponding to the low-adhesive region, and drying the composition by heating or irradiation with ultraviolet light or forming a film to form the insulating binder layer having the recess portion formed on a surface;
Step (B)
a step of detaching the insulating binder layer from the mold; and
Step (C)
a step of filling the recess portion of the insulating binder layer with a low-adhesive region-forming material.

9. A connection structure in which a first electronic component is connected to a second electronic component by anisotropic conductive connection through the anisotropic conductive film according to claim 1.

10. A method of connecting a first electronic component to a second electronic component by anisotropic conductive connection through the anisotropic conductive film according to claim 1, the method comprising:
temporarily adhering the anisotropic conductive film to the second electronic component from a side of the insulating binder layer; mounting the first electronic component on the temporarily adhered anisotropic conductive film; and compression-bonding them from a side of the first electronic component.
